(19) United States
(12) Patent Application Publication
(10) Pub. No.: US 2026/0002264 A1
(43) Pub. Date: Jan. 1, 2026

(54) SUBSTRATE PROCESSING METHOD

(71) Applicant: ASM IP Holding B.V., Almere (NL)

(72) Inventors: SeongMin Han, Yongin-si (KR); Seungju Chun, Hwaseong-si (KR); SungJoo Woo, Yongin-si (KR); SooHyun Baek, Hwaseong-Si (KR); KyungHun Jang, Dongtan (KR); Kwangman Ko, Uiwang-si (KR); InGon Ryu, Suwon-si (KR); HieChul Kim, Hwaseong-si (KR)

(21) Appl. No.: 19/246,961

(22) Filed: Jun. 24, 2025

Related U.S. Application Data
(60) Provisional application No. 63/664,836, filed on Jun. 27, 2024.

(51) Int. Cl. C23C 16/52; C23C 16/44; C23C 16/455

(52) U.S. Cl. CPC C23C 16/52; C23C 16/4408; C23C 16/45536; C23C 16/45553

(57) ABSTRACT

Provided is a method of improving a control time accuracy while a command signal is transmitted to a substrate processing apparatus from a controller, and a process stability while processing a substrate. A method of forming the film using it comprises inputting process control parameters into a first controller, downloading the process control parameters to a second controller from the first controller, and forming the film on the substrate.

### CROSS-REFERENCE TO RELATED APPLICATIONS

This application claims priority to U.S. Provisional Patent Application Ser. No. 63/664,836 filed Jun. 27, 2024 and titled SUBSTRATE PROCESSING METHOD, the disclosure of which is hereby incorporated by reference in its entirety.

### FIELD OF INVENTION

The disclosure relates to a method of processing a substrate, more particularly to a method of improving a control accuracy time and a process stability while processing a substrate, and a method of forming a film on a substrate using it.

### BACKGROUND OF THE DISCLOSURE

A plasma atomic layer deposition (PEALD hereinafter) is a method of forming a film on a substrate at low temperature. In the PEALD method, at least one of source gas and a reactant may be activated by a power applied to a reactor in-situ or remotely to form a film on the substrate. Thus, the PEALD method enables a film to be formed at low temperature, resulting in reducing a thermal budget to underlayers formed on the substrate. That technical advantage leads the PEALD method to be widely used in a chip fabrication.

For commercial application of the PEALD method, it is required to process the substrate fast to achieve a high throughput, reducing a CoO (Cost of Ownership). That may result in fast ON/OFF operations of valves and power source. However, the fast ON/OFF operations may cause a communication delay and inaccurate operations of valves and power source.

FIG. 1 illustrates a conventional communication method of controlling a substrate processing.

As shown in FIG. 1, a first controller may have an input of process control parameters. The process control parameters may be collectively input as a recipe into the first controller. The process control parameters may comprise digital output signals and analog output signals. The digital output signals (DO) may be ON/OFF signals. The digital output signals may be, for instance, valve ON/OFF signals and power source ON/OFF signals. The analog output signals (AO) may be, for instance, a gas flow rate and a power intensity (e.g., a power set value).

The first controller may transmit a command signal (i.e., a recipe comprising digital output signals and analog output signals) to a second controller through an EtherNet communication (i.e., Local Area Network (LAN) communication for data transmission). After that, the digital output signals (i.e., ON/OFF signals) may be transmitted to a valve unit (e.g., a source gas supply valve, a reactant supply valve) and a power source of the substrate processing apparatus via a CPU (Central Processing Unit) and a FPGA (Field Programmable Gate Array) of the second controller. The CPU may act as an Interface between the first controller and the substrate processing apparatus. The analog output signals (i.e., a gas flow rate, a power intensity) may be transmitted to the gas flow controller unit and the power source via the CPU (Central Processing Unit) and the FPGA (Field Programmable Gate Array) of the second controller. The first controller may be a PMC (Process Module Controller) and the second controller may be an I/O (Input/Output) Controller.

The conventional communication method of controlling a substrate processing of FIG. 1, however, may result in an inaccurate control time. FIG. 2 illustrates an RF-ON time fluctuation when a RF-ON time is set at 400 milliseconds in a conventional communication method of controlling a substrate processing. The RF-ON time represents an amount of time the power source is turned on.

In FIG. 2, the RF-ON operation may be performed about 1,800 times. The RF-ON operation represents a turning on the power source to allow a power to be applied to a reactor of the substrate processing apparatus. During the RF-ON operations, the actual RF-ON time may fluctuate ranging from 370 milliseconds to 42 0milliseconds. That is, a control accuracy time (that is, a range of control time fluctuation) may be 50 milliseconds, resulting in not maintaining the 400 milliseconds of the RF-ON set time stably.

FIG. 3 illustrates a source gas supply valve-ON time fluctuation when the source gas supply valve-ON time is set at 100 milliseconds in a conventional communication method of controlling a substrate processing. The source gas supply valve-ON time represents an amount of time that the source valve is open.

In FIG. 3, a source gas supply valve-ON operation may be performed about 1,800 times. During the source gas supply valve-ON operations, the actual source gas supply valve-ON times may fluctuate ranging from 70 milliseconds to 120 milliseconds. That is, the control accuracy time may be 50 milliseconds, resulting in not maintaining the 100 milliseconds of the source gas supply valve-ON set time stably. The source gas supply valve-ON operation represents an opening of the source gas supply valve to allow a flow of the source gas.

The inaccurate control of the RF-ON operation to the power source and the source gas supply valve-ON operation to the valve unit may be caused by a communication delay from the first controller to the substrate processing apparatus via the second controller. The inaccurate control of the RF-ON operation and the source gas supply valve-ON operation may result in low process stability (e.g., a low film uniformity, an undesirable reflected power, etc.).

### SUMMARY OF THE DISCLOSURE

The disclosure relates to a method of processing a substrate, more particularly to a method of improving an accuracy of signal transmission and a process stability while processing a substrate, and a method of forming a film on a substrate using it.

In one or more embodiments, a method of forming a film on a substrate in a reactor may comprise loading the substrate in the reactor, inputting process control parameters into a first controller, downloading the process control parameters to a second controller from the first controller, and forming the film on the substrate by repeating a cycle comprising: applying a first power in a pulsed mode to the reactor from a power source while supplying a source gas and a reactant to the reactor through a valve unit from a gas source, and treating the film by applying a second power to the reactor from the power source while supplying the reactant to the reactor through the valve unit from the gas source, wherein the second controller may control the power source and the valve unit with the process control parameters.

In one or more embodiments, the first power may be applied while supplying the source gas to the reactor, and supplying the source gas may end while applying the first power to the reactor.

In one or more embodiments, the method may further comprise purging the reactor after ending applying the first power and before applying the second power.

In one or more embodiments, the process control parameters may comprise digital output signals.

In one or more embodiments, a control accuracy time of the digital output signals to the power source and the valve unit from the second controller may be about 1 millisecond or below.

In one or more embodiments, the first power may be applied with a duty ratio of between 10% and 50%.

In one or more embodiments, the first power may be applied with an intensity of between about 100W and about 500W at high frequency of between about 10 MHz and about 30 MHz.

In one or more embodiments, the second power may be applied in a continuous mode.

In one or more embodiments, the second power may be applied with an intensity of between about 200W and about 800W at low frequency of between about 300 kHz and about 500 kHz, and with an intensity of between about 1,000W and about 2,000W at high frequency of between about 10 MHz and about 30 MHz.

In one or more embodiments, an impedance matching between the power source and the reactor may be performed through a matching network, wherein the matching network may comprise a plurality of electronically variable discrete capacitors.

In one or more embodiments, the film may comprise at least one of a silicon oxide, a silicon nitride, a silicon oxynitride, a silicon oxycarbide, a silicon carbonitride, a silicon oxycarbonitride, or a mixture thereof.

In one or more embodiments, the source gas may comprise a silicon.

In one or more embodiments, the source gas comprises at least one of (SiH₃)₂NMe, (SiH₃)₂NEt, (SiH₃)₂N(iPr), (SiH₃)₂N(tBu), SiH₃NEt₂, SiH₃N(tBu)₂, SiH₂(NEt₂)₂, SiH₂(NMe₂)₂, SiH₂(NHtBu)₂, SiH₂(NHSiMe₃)₂, SiH₃N(iPr)₂, Si(OEt)₄, SiH(N(Me)₂)₃, SiH₂[N(Et)(Me)]₂, Si₂(NHEt)₆, Si(NHEt)₄, Si(CH₃)₄, or a mixture thereof.

In one or more embodiments, the reactant may comprise at least one of oxygen, nitrogen, or a mixture thereof.

In one or more embodiments, the reactant may comprise at least one of O₂, O₃, N₂, NO₂, N₂O, N₂H₂, NH₃, NH₄, or a mixture thereof.

In one or more embodiments, the film may be formed at between about 200° C. and about 500° C.

In one or more embodiments, a substrate processing apparatus to perform a method of the disclosure may comprise a reactor, a power source to apply a power to the reactor, a matching network to match an impedance between the reactor and the power source, a valve unit to control supplying a source gas and a reactant to the reactor from a gas source, a first controller with digital output signals and analog output signals input, and a second controller, wherein the second controller may be downloaded with the digital output signals and the analog output signals from the first controller to control the substrate processing apparatus, wherein a control accuracy time of the digital output signals and the analog output signals to the substrate processing apparatus may be about 1 millisecond or below.

In one or more embodiments, the matching network of the substrate processing apparatus to perform a method of the disclosure may comprise a plurality of electronically variable discrete capacitors.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a conventional communication method of controlling a substrate processing.

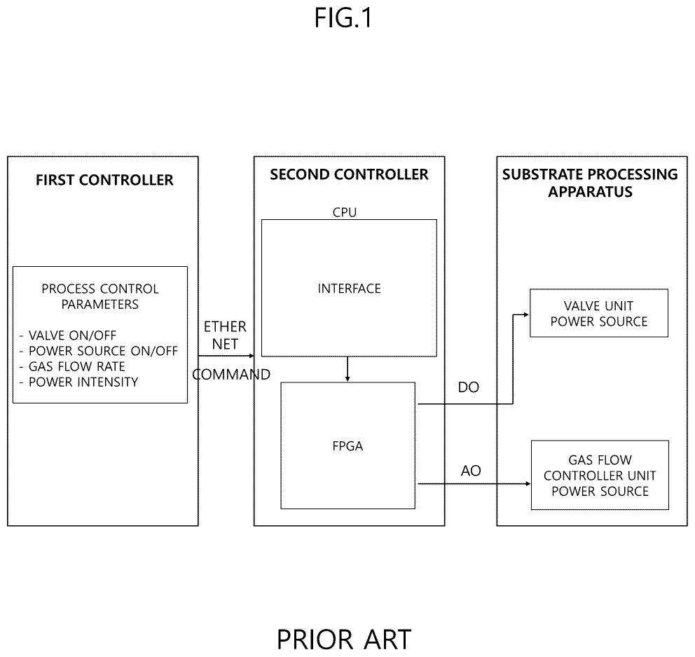

FIG. 2 illustrates a RF-ON time fluctuation when the RF-ON time is set at 400 milliseconds in a conventional communication method of controlling a substrate processing.

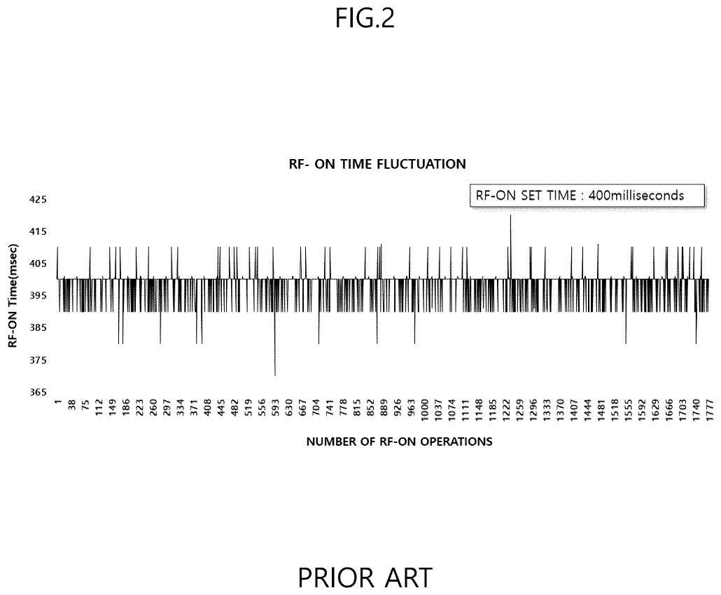

FIG. 3 illustrates a source gas supply valve-ON time fluctuation when the source gas supply valve-ON time is set at 100 milliseconds in a conventional communication method of controlling a substrate processing.

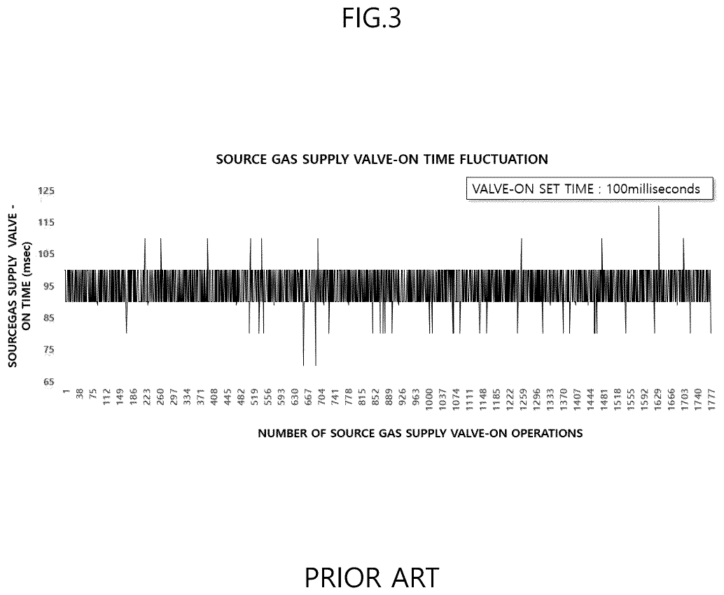

FIG. 4 illustrates a communication method of controlling a substrate processing according to an embodiment of the disclosure.

FIG. 5 illustrates a RF-ON time when the RF-ON time is set at 400 milliseconds according to an embodiment of the disclosure.

FIG. 6 illustrates a source gas supply valve-ON time when the source gas supply valve-ON time is set at 100 milliseconds according to an embodiment of the disclosure.

FIG. 7 illustrates a method of forming a film on a substrate according to an embodiment of the disclosure.

FIG. 8 illustrates details of the STEP 140 of FIG. 7.

FIG. 9 illustrates a timing graph of FIG. 8.

FIG. 10 shows a film conformality on a gap.

FIG. 11 illustrates a forward power and a reflective power occurred when a power is not supplied in T3 in FIG. 9.

FIG. 12 illustrates a forward power and a reflective power occurred when a power is supplied in T3 in FIG. 9.

FIG. 13 illustrates a substrate processing apparatus to process a substrate according to an embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride, or silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

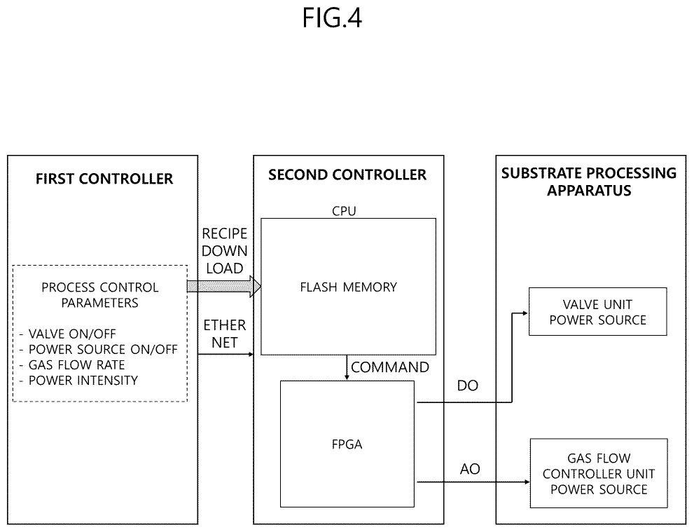

FIG. 4 illustrates a communication method of controlling a substrate processing according to an embodiment of the disclosure.

As shown in FIG. 4, a first controller may have an input of process control parameters. The process control parameters may be collectively input as a recipe into the first controller. The process control parameters may comprise digital output signals and analog output signals. The digital output signals (DO) may be ON/OFF signals. The digital output signals may be, for instance, valve ON/OFF signals and power source ON/OFF signals. The analog output signals (AO) may be, for instance, a gas flow rate and a power intensity (e.g., a power set value). The first controller may be a PMC (Process Module Controller).

Then the second controller may be downloaded with process control parameters from the first controller. For instance, the process control parameters may be downloaded to a CPU (Central Processing Unit) of the second controller. The CPU may comprise a Flash Memory and the process control parameters may be downloaded to the Flash Memory. The download may be performed through an EtherNet communication. The second controller may be an I/O (Input/Output) Controller.

The second controller may transmit a command signal (i.e., a recipe comprising digital output signals and analog output signals) to the substrate processing apparatus directly via the FPGA (Field Programmable Gate Array) of the second controller. The digital output signals (i.e., ON/OFF signals) may be transmitted to the valve unit and the power source, and the analog output signals (i.e., a gas flow rate, a power intensity) may be transmitted to the gas flow controller unit and the power source.

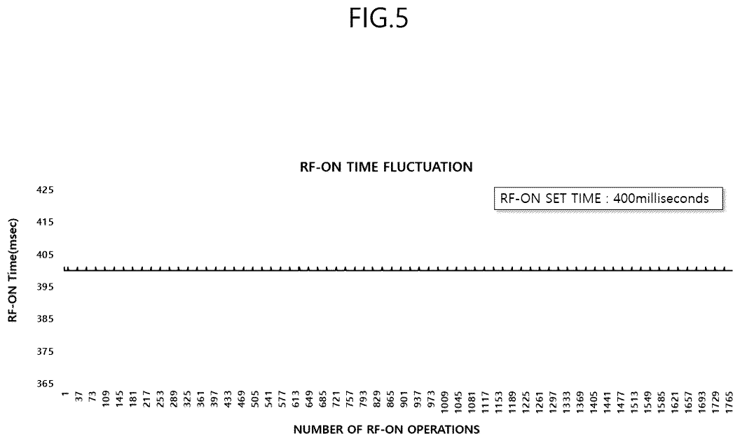

FIG. 5 illustrates a RF-ON time fluctuation when the RF-ON time is set at 400 milliseconds according to an embodiment of the disclosure.

In FIG. 5, the RF-ON operation may be performed about 1,800 times. As shown in FIG. 5, the actual RF-ON time is maintained stably at 400 milliseconds, a RF-ON set time, without a communication delay. The RF-ON time may fluctuate ranging from 400 milliseconds to 401 milliseconds. That is, 400.04 milliseconds on average. Therefore, the control accuracy time (i.e., a range of control time fluctuation) may be 1 millisecond or below, resulting in maintaining the 400 milliseconds of the RF-ON set time stably.

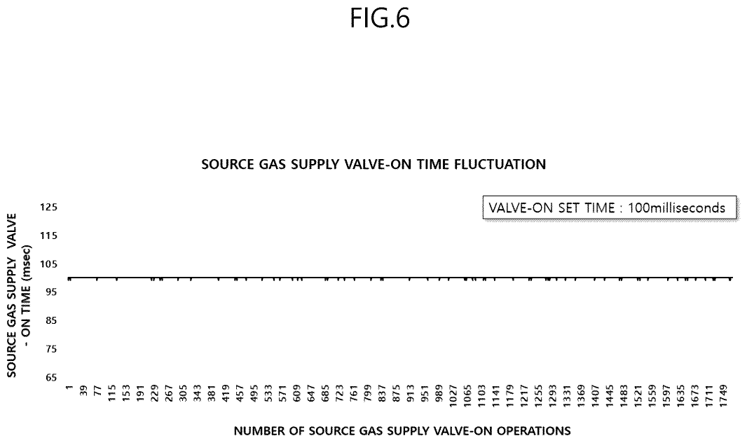

FIG. 6 illustrates a source gas supply valve-ON time fluctuation when the source gas supply valve-ON time is set at 100 milliseconds according to an embodiment of the disclosure.

In FIG. 6, the source gas supply valve-ON operation may be performed about 1,800 times. As shown in FIG. 6, the actual source gas supply valve-ON time is maintained stably at 100 millisecondss, a source gas supply valve-ON set time, without a communication delay. The source gas supply valve-ON time may fluctuate ranging from 99 milliseconds to 100 milliseconds. That is, 99.96 milliseconds on average. Therefore, the control accuracy time (i.e., a range of control time fluctuation) may be 1millisecond or below, resulting in maintaining the 100 milliseconds of the source gas supply valve-ON set time stably.

In an embodiment of the disclosure, the control accuracy time of the digital output signals to the power source and the valve unit (e.g., a source gas supply valve, a reactant supply valve) from the second controller may be about 1 millisecond or below.

Therefore, the method of controlling a substrate processing of the disclosure as shown in FIG. 4 may have a technical advantage of improving the control accuracy time (i.e., a low fluctuation of control accuracy time) and a process stability accordingly.

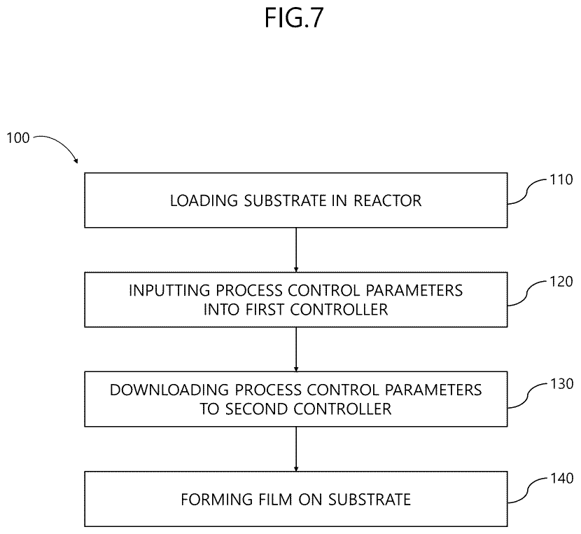

FIG. 7 illustrates a method of forming a film on a substrate according to an embodiment of the disclosure.

In STEP 110 of the method 100, a substrate may be loaded in a reactor of a substrate processing apparatus. The substrate may comprise a recess (e.g., a gap, a trench, a via hole, 3D vertical structure etc.), or a flat surface, or a mixture thereof.

In STEP 120, process control parameters may be input into a first controller. The process control parameters may be collectively input as a recipe into the first controller. The process control parameters may comprise digital output signals and analog output signals. The digital output signals (DO) may be ON/OFF signals. The digital output signals may be, for instance, valve ON/OFF signals and power source ON/OFF signals. The analog output signals (AO) may be, for instance, a gas flow rate and a power intensity (e.g., a power set value).

In STEP 130, the process control parameters may be downloaded to a second controller from the first controller. In more detail, the process control parameters may be downloaded to a CPU (Central Processing Unit) of the second controller.

In STEP 140, a film may be formed on the substrate. The film may be formed via a plasma-assisted process. For instance, the film may be formed via PEALD method, or Pulsed PECVD method, or PECVD method. The valve operation (e.g., a source gas supply valve-ON) and the power source operation (e.g., RF-ON) of the substrate processing apparatus may be controlled by the second controller directly.

The second controller may transmit a command signal (i.e., a recipe comprising process control parameters (e.g., digital output signals and analog output signals)) to the substrate processing apparatus from the second controller directly as shown in FIG. 4 so that a communication delay may be reduced, and a control accuracy time and a process stability may improve.

The film formed in STEP 140 may be a silicon-containing film. For instance, the film may be at least one of a silicon oxide, a silicon nitride, a silicon oxynitride, a silicon oxycarbide, a silicon carbonitride, a silicon oxycarbonitride, or a mixture thereof.

The film in STEP 140 may be formed by supplying a source gas and a reactant simultaneously, or sequentially and alternately while applying a power to the reactor. The source gas may comprise a silicon and the reactant may comprise at least one of oxygen, nitrogen, or a mixture thereof.

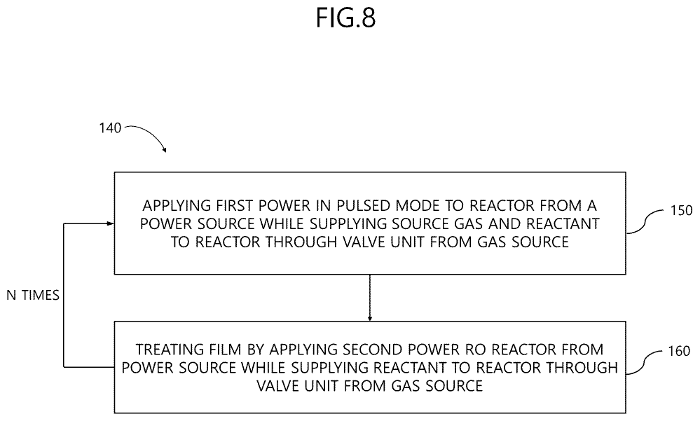

FIG. 8 illustrates details of the STEP 140 of FIG. 7.

In STEP 150, the film may be formed by applying a first power in a pulsed mode to the reactor from a power source while supplying a source gas and a reactant to the reactor through a valve unit from a gas source. The gas source may comprise a source gas source and a reactant source. The valve unit may comprise a source supply valve and a reactant supply valve. The second controller may control the power source and the valve unit with the process control parameters (e.g., a RF-ON digital output signal, a source gas supply valve-ON digital output signal).

In STEP 150, the first power may be applied while supplying the source gas, and supplying the source gas may end while applying the first power.

In a substrate processing apparatus, the source gas may take some time to reach the reactor through a gas supply pipe due to a physical distance between the gas source and the reactor.

Given the source gas may still be in the gas supply pipe at the beginning of supplying the source gas, the reactor may not be filled with a predetermined amount of the source gas at the beginning of supplying the source gas. Therefore, it is desirable to apply the first power while supplying the source gas. In other words, the first power may be applied when the reactor is filled with a predetermined amount of the source gas, resulting in improving a plasma stability and a process reliability.

The first power may continue to be applied to the reactor after stopping supplying the source gas to the reactor. Although the supply of the source gas ends, the residual source gas in the gas supply pipe may continue to be supplied to the reactor and the film may continue to be formed by the first power without continuing to supply the source gas. Thus, unnecessary source consumption may be prevented.

In STEP 150, the first power may be applied in pulsed mode with a duty ratio of between 10% and 50% with 500 Hz of pulsing frequency. In an embodiment of the disclosure, the first power may be a high frequency RF power (HRF). For instance, the first power may be applied with an intensity of between about 100W and about 500W at high frequency of between about 10 MHz and about 30 MHz.

In STEP 160, treating the film may be performed by applying a second power to the reactor from the power supply unit while supplying the reactant to the reactor through the valve unit from the gas source. The STEP 160 may be performed to modify film properties. For instance, a wet etch rate (WER), or a film density may be modified by treating the film.

In STEP 160, the second power may be applied in a continuous mode. In an embodiment of the disclosure, the second power may be at least one of a high frequency RF power (HRF), a low frequency RF power (LRF), or a combination thereof. For instance, the second power may be applied with an intensity of between about 200W and about 800W at low frequency of between about 300 kHz and about 500 kHz, and with an intensity of between about 1,000W and about 2,000W at high frequency of between about 10 MHz and about 30 MHz.

The STEP 150 and the STEP 160 may be repeated a plurality of times (e.g., N times) until a desired film thickness is achieved.

In an embodiment of the disclosure, the reactant may be supplied continuously throughout a cycle (i.e., throughout the STEP 150 and the STEP 160).

The method 100 may further comprise supplying an inert gas as a purge gas continuously throughout the cycle (i.e., throughout the STEP 150 and the STEP 160).

The method 100 may be performed at between about 200° C. and about 500° C. In other words, the film may be formed at between about 200° C. and about 500° C.

In STEP 140, when applying the power (i.e., the first power, the second power) to the reactor, an impedance matching between the power source and the reactor may be performed through a matching network. The matching network may be an EVC matching network comprising a plurality of electronically variable discrete capacitors, resulting in a fast matching compared to the conventional mechanical matching network.

The film formed according to the method 100 may comprise at least one of a silicon oxide, a silicon nitride, a silicon oxynitride, a silicon oxycarbide, a silicon carbonitride, a silicon oxycarbonitride, or a mixture thereof.

The source gas to form the film may comprise a silicon. For instance, the source gas may comprise at least one of (SiH₃)₂NMe, (SiH₃)₂NEt, (SiH₃)₂N(iPr), (SiH₃)₂N(tBu), SiH₃NEt₂, SiH₃N(tBu)₂, SiH₂(NEt₂)₂, SiH₂(NMe₂)₂, SiH₂(NHtBu)₂, SiH₂(NHSiMe₃)₂, SiH₃N(iPr)₂, Si(OEt)₄, SiH(N(Me)₂)₃, SiH₂[N(Et)(Me)]₂, Si₂(NHEt)₆, Si(NHEt)₄, Si(CH₃)₄, or a mixture thereof.

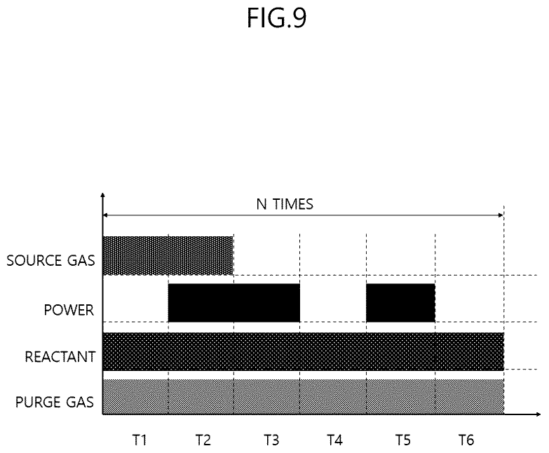

The reactant to form the film may comprise at least one of oxygen, nitrogen, or a mixture thereof. For instance, the reactant may comprise at least one of O₂, O₃, N₂, NO₂, N₂O, N₂H₂, NH₃, NH₄, or a mixture thereof. FIG. 9 illustrates a timing graph of FIG. 8.

In T1 of FIG. 9, a source gas and a reactant may be supplied to a reactor, without applying a power to the reactor. That is, a source supply valve may be open in T1. A part of the source gas supplied in T1 may still be in a gas supply pipe. In other words, the reactor may not be filled with a predetermined amount of the source gas.

In T2, the source gas and the reactant may continue to be supplied to the reactor, resulting in filling the reactor with the predetermined amount of the source gas. A first power may be applied to the reactor in T2 while the source gas continues to be supplied and activate the source gas and the reactant to form a film on a substrate. The first power may be applied in a pulsed mode in T2.

In T3, supplying the source gas may end while the first power may continue to be applied. In other words, the source gas supply valve may be closed, but the remaining source gas and the reactant in the gas supply pipe may continue to be supplied to the reactor and be activated by the first power, resulting in forming the film. The first power may still be applied in a pulsed mode in T3.

In T4, the reactor may be purged with applying the first power ended. The reactor may be purged after ending applying the first power and before applying a second power. An inert gas as a purge gas may be supplied to the reactor to remove a residual source gas and byproducts from the reactor.

In T5, treating the film may be performed by applying the second power to the reactor with reactant supplied. The film properties (i.e., a wet etch rate (WER), a film density, a film composition etc.) may be modified in T1.

In T6, purging the reactor may be performed by supplying the purge gas. The T1 to T6 may comprise a cycle and be repeated a plurality of times (N times)

As shown in FIG. 9, the reactant and the purge gas may be supplied continuously throughout the cycle.

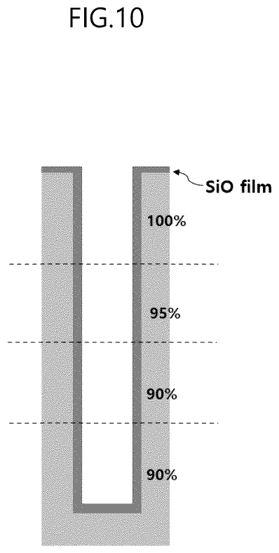

FIG. 10 shows a film conformality.

As shown in FIG. 10, a silicon oxide film may be conformally formed along the surface of the gap from the top to bottom. The gap may comprise a 2 mm to 6 mm of width and a 30 mm to 70 mm of depth. A thickness of the silicon oxide film formed on the side wall may be 90% or above of the thickness of silicon oxide film formed on the top. Thus, a method of forming a film according to an embodiment of the disclosure may form a conformal film on the gap.

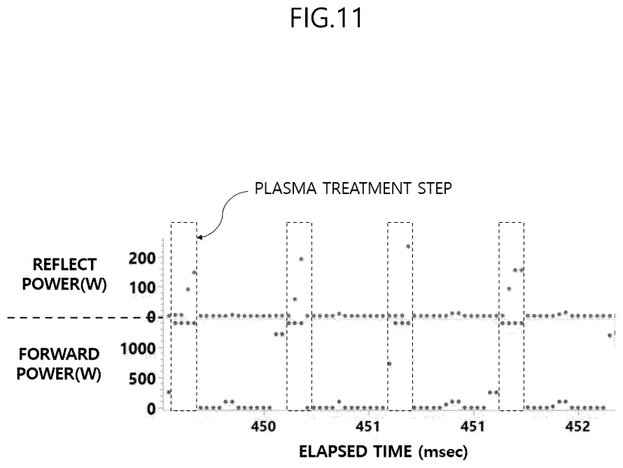

FIG. 11 illustrates a forward power and a reflective power occur when a power (i.e., a first power) is not supplied in T3 in FIG. 9. As shown in FIG. 11, A 100W to 200W of a reflective power occurs (as marked with arrows) at plasma treatment step (i.e., T5). That is, a 100W to 200W of reflective power is not used in forming form a film, resulting in a low process reliability.

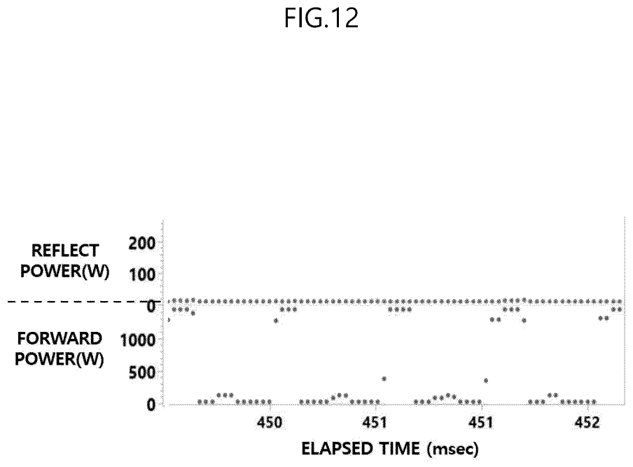

FIG. 12 illustrates a forward power and a reflective power occurring when a power (i.e., a first power) is supplied in T3 in FIG. 9. As shown in FIG. 12, a reflective power does not occur, resulting in a high process reliability. Thus, a method of forming a film of FIG. 9 according to an embodiment of the disclosure may have a technical advantage of more stable process and high process reliability.

Table 1 shows test conditions to form a silicon oxide film according to an embodiment of the disclosure. Test conditions in Table 1 may correspond to FIG. 9.

TABLE 1
Test conditions to form a silicon oxide film

| Item | | Conditions |
|---|---|---|
| Process time per | Source gas flow-on | 0.05 to 0.2 (preferably 0.08 to 0.15) |
| step (second) | Source gas flow-on, first | 0.01 to 0.1 (preferably 0.04 to 0.08) |
| | power-on | |
| | Source gas flow-off, first | 0.01 to 0.1 (preferably 0.04 to 0.08) |
| | power-on | |
| | Purge | 0.1 to 0.8 (preferably 0.3 to 0.6) |
| | Second power-on | 0.1 to 0.8 (preferably 0.3 to 0.6) |
| | Purge | 0.01 to 0.1 (preferably 0.04 to 0.08) |
| Gas flow | Source gas carrier Ar | 2,000 to 5,000 (preferably 2,500 to |
| condition (sccm) | | 4,000) |
| | Purge Ar (continuous flow) | 500 to 2,000 (preferably 800 to 1,500) |
| | O₂ (continuous flow) | 500 to 2,000 (preferably 800 to 1,500) |
| Plasma condition | First power (HRF) | HRF 100 W to 500 W (preferably 150 to |
| | | 350 W) |
| | | Duty ratio 10% to 50% (preferably 15% |
| | | to 35%) |
| | Second power (HRF/LRF) | HRF 1,000 W to 2,000 W (preferably |
| | | 1,200 W to 1,800 W) |
| | | LRF 300 W to 1,000 W (preferably |
| | | 500 W to 800 W) |
| Source gas | | Silicon-containing gas |
| Process temperature (° C.) | | 200 to 500 |
| Process pressure (Torr) | | 1 to 5 |

As shown in Table 1, a cycle time of an embodiment of the disclosure may be very short (e.g., about 1 second or below per cycle). Therefore, a fast substrate processing may be facilitated. In more detail, the fast substrate processing may result from a stable control accuracy time during a substrate processing without a communication delay and a fast impedance matching between the reactor and the power source by the EVC matching network.

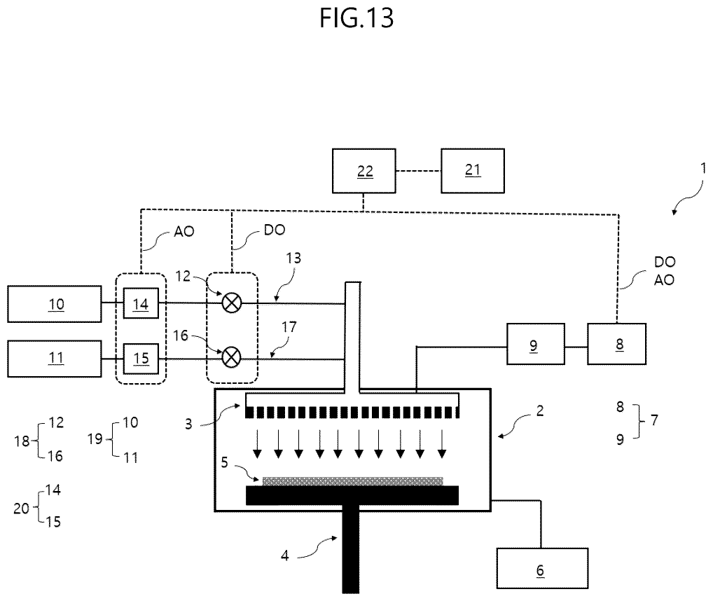

FIG. 13 illustrates a substrate processing apparatus to process a substrate according to an embodiment of the disclosure.

In FIG. 13, the substrate processing apparatus 1 may comprise a reactor 2, a gas supply unit 3, a substrate support unit (heating block) 4, a substrate 5, an exhaust unit 6, a power supply unit 7, a power source 8, a matching network 9, a source gas supplier 10, a reactant supplier 11, a source gas supply valve 12, a source gas supply pipe 13, a source gas flow controller 14, a reactant flow controller 15, a reactant supply valve 16, a reactant supply pipe 17, a valve unit 18, a gas source 19, a gas flow controller unit 20, a first controller 21, and a second controller 22.

The power supply unit 7 may comprise the power source 8 and the matching network 9. The power source 8 may be a power generator to generate at least one of a high frequency RF power (HRF), a low frequency RF power (LRF), or a mixture thereof.

The matching network 9 may match an impedance between the reactor 2 and the power source 8. The matching network 9 may comprise an electronically variable discrete capacitor (EVC) array, a common bottom electrode, an individual top electrode connected to each EVC, and a switching mechanism comprising PIN diodes. When carrying out an impedance matching between the power source 8 and the reactor 2, various combinations among capacitors may be made swiftly. Thus, it may enable to find the matching positions fast, compared to variable vacuum capacitors (VVCs) of the existing mechanical matching network. U.S. Pat. No. 7,251,121 (incorporated by reference) describes a mechanism of the EVC matching network in detail. By using the EVC matching network, the impedance matching time may be significantly reduced and a reflected power may also be significantly eliminated.

The gas source 19 may comprise the source gas supplier 10 and the reactant supplier 11. The source gas supplier 10 may comprise a source vessel containing a source gas. The reactant supplier 11 may comprise a reactant vessel containing a reactant. The gas source may further comprise another gas supplier (e.g., inert gas).

The valve unit 18 may control supplying a source gas and a reactant to the reactor from the gas source 19. The valve unit 18 may comprise the source gas supply valve 12 and the reactant supply valve 16. The valve unit 18 may control the supply of the source gas and the reactant to the reactor 2 from the gas source 19 by ON/OFF operations.

The gas flow controller unit 20 may comprise the source gas flow controller 14 and the reactant flow controller 15. The source gas flow controller 14 may control the flow rate of the source gas and the reactant flow controller 15 may control the flow rate of the reactant. The source gas flow controller 14 and the reactant flow controller 15 may be a mass flow controller (MFC).

The source gas may be supplied to the reactor 2 from the source gas supplier 10 via the source gas supply pipe 13. The source gas flow controller 14 and the source gas supply valve 12 may control the supply of the source gas.

The reactant may be supplied to the reactor 2 from the reactant supplier 11 via the reactant supply pipe 17. The reactant flow controller 15 and the reactant supply valve 16 may control the supply of the reactant.

As indicated with dotted lines in FIG. 13, the power source 8, the valve unit 18 and the gas flow controller unit 20 may be controlled by the first controller 21 and the second controller 22. The first controller 21 may have an input of process control parameters as a recipe. The first controller 21 may be a PMC (Process Module Controller). The second controller may be an I/O (Input/Output) Controller. The first controller 21 may communicate with the second controller 22 through an EtherNet communication (i.e., Local Area Network (LAN) communication for data transmission).

The process control parameters may be collectively input into the first controller 21 in a form of recipe. The process control parameters may comprise digital output signals and analog output signals. The digital output signals (DO) may be ON/OFF signals. The digital output signals may be, for instance, valve ON/OFF signals and power source ON/OFF signals. The analog output signals (AO) may be, for instance, a gas flow rate, a power intensity (e.g., a power set value).

The second controller 22 may comprise a CPU (Central Processing Unit) and an FPGA (Field Programmable Gate Array) to transmit a command signal (i.e., a recipe comprising the digital output signals and the analog output signals) to the substrate processing apparatus.

A control accuracy time of the digital output signals and the analog output signals to the substrate processing apparatus from the second controller may be about 1 millisecond or below.

The second controller 22 may be downloaded with the process control parameters from the first controller 21 to control the substrate processing apparatus. The second controller 22 may transmit the command signal (e.g., the digital output signals (DO)) to the power source 8 and the valve unit 18 to control the operations of the power source 8 and the valve unit 18. The second controller 22 may transmit the command signal (e.g., the analog output signals (AO)) to the power source 8 and the gas flow controller unit 20 to control the power intensity of the power source 8 and the gas flow controller unit 20.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of forming a film on a substrate in a reactor, comprising:
loading a substrate in a reactor;
inputting process control parameters into a first controller;
downloading the process control parameters to a second controller from the first controller; and
forming the film on the substrate by repeating a cycle comprising:
applying a first power in a pulsed mode to the reactor from a power source while supplying a source gas and a reactant to the reactor through a valve unit from a gas source; and
treating the film by applying a second power to the reactor from the power source while supplying the reactant to the reactor through the valve unit from the gas source,
wherein the second controller controls the power source and the valve unit with the process control parameters.

2. The method of claim 1, wherein the first power is applied to the reactor while supplying the source gas, and supplying the source gas ends while applying the first power to the reactor.

3. The method of claim 2, further comprising purging the reactor after ending applying the first power and before applying the second power.

4. The method of claim 1, wherein the process control parameters comprise digital output signals.

5. The method of claim 4, wherein a control accuracy time of the digital output signals to the power source and the valve unit from the second controller is about 1 millisecond or below.

6. The method of claim 1, wherein the first power is applied with a duty ratio of between 10% and 50%.

7. The method of claim 1, wherein the first power is applied with an intensity of between about 100W and about 500W at high frequency of between about 10 MHz and about 30 MHz.

8. The method of claim 1, wherein the second power is applied in a continuous mode.

9. The method of claim 8, wherein the second power is applied with an intensity of between about 200W and about 800W at low frequency of between about 300 kHz and about 500 kHz, and with an intensity of between about 1,000W and about 2,000W at high frequency of between about 10 MHz and about 30 MHz.

10. The method of claim 1, wherein an impedance matching between the power source and the reactor is performed through a matching network, wherein the matching network comprises a plurality of electronically variable discrete capacitors.

11. The method of claim 1, wherein the film comprises at least one of a silicon oxide, a silicon nitride, a silicon oxynitride, a silicon oxycarbide, a silicon carbonitride, a silicon oxycarbonitride, or a mixture thereof.

12. The method of claim 1, wherein the source gas comprises a silicon.

13. The method of claim 12, wherein the source gas comprises at least one of (SiH₃)₂NMe, (SiH₃)₂NEt, (SiH₃)₂N(iPr), (SiH₃)₂N(tBu), SiH₃NEt₂, SiH₃N(tBu)₂, SiH₂(NEt₂)₂, SiH₂(NMe₂)₂, SiH₂(NHtBu)₂, SiH₂(NHSiMe₃)₂, SiH₃N(iPr)₂, Si(OEt)₄, SiH(N(Me)₂)₃, SiH₂[N(Et)(Me)]₂, Si₂(NHEt)₆, Si(NHEt)₄, Si(CH₃)₄, or a mixture thereof.

14. The method of claim 1, wherein the reactant comprises at least one of oxygen, nitrogen, or a mixture thereof.

15. The method of claim 14, wherein the reactant comprises at least one of O₂, O₃, N₂, NO₂, N₂O, N₂H₂, NH₃, NH₄, or a mixture thereof.

16. The method of claim 1, wherein the film is formed at between about 200° C. and about 500° C.

17. The method of claim 1, wherein the reactant is supplied continuously throughout the cycle.

18. The method of claim 1, further comprising supplying an inert gas as a purge gas continuously throughout the cycle.

19. A substrate processing apparatus to perform a method of claim 1, comprising:
a reactor;
a power source to apply a power to the reactor;
a matching network to match an impedance between the reactor and the power source;
a valve unit to control supplying a source gas and a reactant to the reactor from a gas source;
a first controller with digital output signals and analog output signals input; and
a second controller,
wherein the second controller is downloaded with the digital output signals and the analog output signals from the first controller to control the substrate processing apparatus,
wherein a control accuracy time of the digital output signals and the analog output signals to the substrate processing apparatus from the second controller is about 1 millisecond or below.

20. The substrate processing apparatus of claim 19, wherein the matching network comprises a plurality of electronically variable discrete capacitors.
